(19) United States
(12) Patent Application Publication
(10) Pub. No.: US 2022/0336235 A1
(43) Pub. Date: Oct. 20, 2022

(54) VALVE BOX MODULE, SEMICONDUCTOR DEVICE MANUFACTURING SYSTEM AND METHOD FOR MANUFACTURING SEMICONDUCTOR DEVICE

(71) Applicant: TAIWAN SEMICONDUCTOR MANUFACTURING COMPANY LTD., Hsinchu (TW)

(72) Inventors: FANG-PIN CHIANG, TAICHUNG CITY (TW); HENG-YI TSENG, HSINCHU COUNTY (TW); CHI-TUNG LAI, HSINCHU (TW); SHUN CHAN TENG, HSINCHU (TW); HUNG-CHIEH CHEN, HSINCHU (TW)

(21) Appl. No.: 17/232,563

(22) Filed: Apr. 16, 2021

(51) Int. Cl. H01L 21/67; F16K 31/12; G05D 16/20

(52) U.S. Cl. CPC H01L 21/67017; F16K 31/12; G05D 16/2013

(57) ABSTRACT

A semiconductor device manufacturing system and a method for manufacturing semiconductor device are provided. The semiconductor device manufacturing system comprises a valve box module, a controller, a purge gas source and at least one semiconductor manufacturing tool. The valve box module includes at least one stick and a first gas line in fluid communication with the at least one stick. Further, the first gas line includes a pneumatic valve and a pressure transmitter downstream of the pneumatic valve. The controller connects to the pneumatic valve and the pressure transmitter of the first gas line. The purge gas source is in fluid communication with the first gas line. The at least one semiconductor manufacturing tool is coupled to the at least one stick.

### BACKGROUND

Generally speaking, a VMB (Valve manifold Box) used for outputting and inputting semiconductor process gas comprises a process gas line coupled to a process gas source, a plurality of sticks respectively coupled to a plurality of semiconductor manufacturing tools and a purge gas line coupled to a purge gas source. The purge gas line connects the sticks and configured to supply the purge gas into the sticks, and the process gas line connects the sticks and configured to supply the process gas into the sticks. Thus, the VMB is configured to supply the process gas into different sticks at the same time from the single process gas line and to supply the purge gas into different sticks at the same time from the single purge gas line.

Before the semiconductor manufacturing tool is detached from the stick, the stick should be purged by the purge gas from the purge gas line.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic view of a semiconductor device manufacturing system in accordance with some embodiments of the present disclosure.

FIG. 2 is a flow chart representing exemplary operations of the method for manufacturing a semiconductor device by the semiconductor device manufacturing system, in accordance with some embodiments of the present disclosure.

FIG. 3 is a flow chart representing exemplary operations of the method for manufacturing a semiconductor device by the semiconductor device manufacturing system, in accordance with some embodiments of the present disclosure.

FIG. 4 is a flow chart representing exemplary operations of the method for manufacturing a semiconductor device by the semiconductor device manufacturing system, in accordance with some embodiments of the present disclosure.

FIG. 5 is a flow chart representing exemplary operations of the method for manufacturing a semiconductor device by the semiconductor device manufacturing system, in accordance with some embodiments of the present disclosure.

FIG. 6 is a flow chart representing exemplary operations of the method for manufacturing a semiconductor device by the semiconductor device manufacturing system, in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

This description of illustrative embodiments is intended to be read in connection with the accompanying drawings, which are to be considered part of the entire written description. In the description of embodiments disclosed herein, any reference to direction or orientation is merely intended for convenience of description and is not intended in any way to limit the scope of the present disclosure. Relative terms such as “lower.” “upper,” “horizontal,” “vertical,”, “above,” “below,” “up,” “down,” “top” and “bottom” as well as derivative thereof (e.g., “horizontally,” “downwardly,” “upwardly,” etc.) should be construed to refer to the orientation as then described or as shown in the drawing under discussion. These relative terms are for convenience of description only and do not require that the apparatus be constructed or operated in a particular orientation. Terms such as “attached,” “affixed,” “connected” and “interconnected,” refer to a relationship wherein structures are secured or attached to one another either directly or indirectly through intervening structures, as well as both movable or rigid attachments or relationships, unless expressly described otherwise. Moreover, the features and benefits of the disclosure are illustrated by reference to the embodiments. Accordingly, the disclosure expressly should not be limited to such embodiments illustrating some possible non-limiting combination of features that may exist alone or in other combinations of features; the scope of the disclosure being defined by the claims appended hereto.

A common valve manifold box (VMB) is a separate dedicated apparatus unit for delivery of gas from single source vessel to multiple points of use. The VMB has an inlet port to accept gas from the gas cabinet, with the port being coupled to the gas dispensing line from the gas cabinet, and the VMB functioning to split the gas stream from the gas cabinet dispensing line into multiple streams that are discharged from the valve manifold box in multiple outlets. The gas pressure of the dispensed gas stream may be regulated at the gas cabinet or at each individual outlet of the VMB, e.g., by provision of flow control valves, regulators, restrictive flow orifices, or other gas pressure-regulating elements, at such locations.

The VMB is typically constructed to allow for independent monitoring, control and maintenance of each so-called process “stick,” i.e., the portion of the flow circuitry that is associated with a given outlet port of the VMB and functions to feed gas from the VMB to the associated downstream process tool.

The independent character of the respective sticks that are associated with the VMB and fed from the single gas supply in the gas cabinet coupled to the VMB, permits termination of gas flow through one or more of the sticks that connected with corresponding one(s) of the multiple semiconductor tools being served by the single gas supply in the gas cabinet, without interruption of gas flow through the other stick(s) serving other process tool(s).

Before the process tool is detached from the VMB, a manual cycle-purge should be performed on the stick coupled to the process tool.

Present disclosure provides a semiconductor device manufacturing system that instantly and efficiently purges the stick coupled to the process tool before the process tool is detached from the VMB or the like.

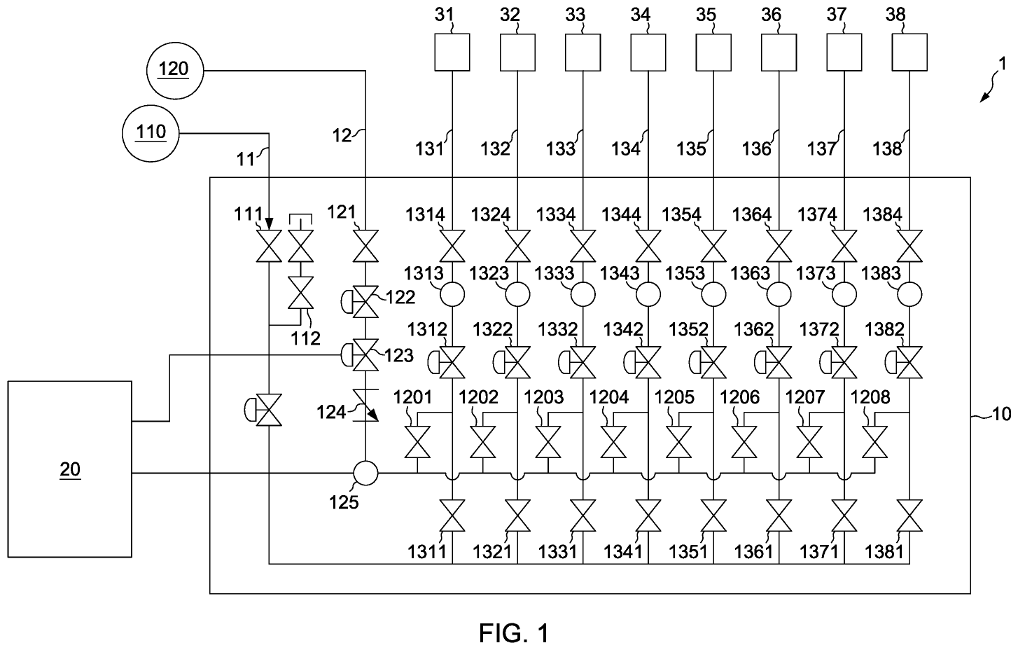

FIG. 1 is a schematic view of a semiconductor device manufacturing system 1 in accordance with some embodiments of the present disclosure. In some embodiments of the present disclosure, the semiconductor device manufacturing system 1 includes a valve box module 10, a controller 20 connecting with the valve box module 10, a process gas source 110 connecting with the valve box module 10, a purge gas source 120 connecting with the valve box module 10 and semiconductor manufacturing tools 31, 32, 33, 34, 35, 36, 37, 38 connecting with the valve box module 10. The purge gas source 120 is configured to provide a purge gas. In some embodiments of the present disclosure, the purge gas includes nitrogen gas.

In some embodiments of the present disclosure, the valve box module 10 includes a process gas line 11, a purge gas line 12 and sticks 131, 132, 133, 134, 135, 136, 137 and 138. The process gas line 11 may be connected with the sticks 131, 132, 133, 134, 135, 136, 137 and 138 and joined in gas flow communication to the sticks 131, 132, 133, 134, 135, 136, 137 and 138. The purge gas line 12 may be connected with the sticks 131, 132, 133, 134, 135, 136, 137 and 138 and joined in gas flow communication to the sticks 131, 132, 133, 134, 135, 136, 137 and 138.

The process gas line 11 may be coupled to the process gas source 110 and include a valve 111. The valve 111 is configured to be selectively opened or closed so as to control the process gas from the process gas source 110 to flow into the VMB 10 and the process gas line (downstream of the valve 111). In some embodiments of the present disclosure, the process gas line 11 may further include an expansion port 112.

As shown in FIG. 1, the process gas line 11 may be connected with the sticks 131, 132, 133, 134, 135, 136, 137 and 138. The stick 131 may include a first valve 1311, a regulator valve 1312, a pressure transmitter 1313 and a second valve 1314, and the stick 131 may further connect with the semiconductor manufacturing tool 31. The stick 132 may include a first valve 1321, a regulator valve 1322, a pressure transmitter 1323 and a second valve 1324, and the stick 132 may further connect with the semiconductor manufacturing tool 32. The stick 133 may include a first valve 1331, a regulator valve 1332, a pressure transmitter 1333 and a second valve 1334, and the stick 133 may further connect with the semiconductor manufacturing tool 33. The stick 134 may include a first valve 1341, a regulator valve 1342, a pressure transmitter 1343 and a second valve 1344, and the stick 134 may further connect with the semiconductor manufacturing tool 34. The stick 135 may include a first valve 1351, a regulator valve 1352, a pressure transmitter 1353 and a second valve 1354, and the stick 135 may further connect with the semiconductor manufacturing tool 35. The stick 136 may include a first valve 1361, a regulator valve 1362, a pressure transmitter 1363 and a second valve 1364, and the stick 136 may further connect with the semiconductor manufacturing tool 36. The stick 137 may include a first valve 1371, a regulator valve 1372, a pressure transmitter 1373 and a second valve 1374, and the stick 137 may further connect with the semiconductor manufacturing tool 37. The stick 138 may include a first valve 1381, a regulator valve 1382, a pressure transmitter 1383 and a second valve 1384, and the stick 138 may further connect with the semiconductor manufacturing tool 38. These valves in the respective sticks can be selectively opened or closed to facilitate flow of process gas through the sticks containing open valves, to the semiconductor manufacturing tools 31, 32, 33, 34, 35, 36, 37 and/or 38, as are operated at a given time in the semiconductor manufacturing operation.

Further, the purge gas line 12 may be coupled to the purge gas source 120. In some embodiments of the present disclosure, the purge gas line 12 includes a valve 121, a regulator valve 122, a pneumatic valve 123, a check valve 124 and a pressure transmitter 125. The valve 121 may be adjacent to the purge gas source 120 and configured to be selectively opened or closed to control the purge gas from the purge gas source 120 into the purge gas line 12. The regulator valve 122 is downstream of the valve 121. The pneumatic valve 123 is downstream of the regulator valve 122. The check valve 124 is downstream of the pneumatic valve 123. The pressure transmitter 125 is downstream of the check valve 124. Moreover, referring to FIG. 1, the respective sticks 131, 132, 133, 134, 135, 136, 137 and 138 are coupled with purge gas line 12, and the purge gas line 12 includes respective purge gas line loops containing purge valves 1201, 1202, 1203, 1204, 1205, 1206, 1207 and 1208, to provide flow of purge gas to the sticks 131, 132, 133, 134, 135, 136, 137 and 138, respectively. As shown in FIG. 1, the purge valves 1201, 1202, 1203, 1204, 1205, 1206, 1207 and 1208 may be adjacent to the joints between the respective purge gas line loops of the purge gas line 12 and the respective sticks 131, 132, 133, 134, 135, 136, 137 and 138.

The pneumatic valve 123 and the pressure transmitter 125 may connect to the controller 20. In some embodiments of the present disclosure, the controller 20 includes a programmable logic controller (PLC). The pressure transmitter 125 is configured to detect the gas pressure in the purge gas line 12 and/or to detect the gas pressure in the stick(s) 131, 132, 133, 134, 135, 136, 137 and/or 138 when the purge valve(s) 1201, 1202, 1203, 1204, 1205, 1206, 1207 and/or 1208 are opened. Further, the pressure transmitter 125 may transfer the pressure value which it detected to the controller 20. The user may learn the gas pressure in the purge gas line 12 and/or in the stick(s) 131, 132, 133, 134, 135, 136, 137 and/or 138 by the controller 11. The controller 20 may control the pneumatic valve 123 based on the pressure value from the pressure transmitter 125. In some embodiments of the present disclosure, when the pressure transmitter 125 detects that the gas pressure value in the stick(s) 131, 132, 133, 134, 135, 136, 137 and/or 138 reaches a specific pressure value, the controller 20 may open the pneumatic valve 123, so that the purge gas from the purge gas source 120 passes through the pneumatic valve 123 and then flows into the stick(s) 131, 132, 133, 134, 135, 136, 137 and/or 138 through the opened purge valve(s) 1201, 1202, 1203, 1204, 1205, 1206, 1207 and/or 1208. In some embodiments of the present disclosure, when the pressure transmitter 125 detects that the gas pressure value in the stick(s) 131, 132, 133, 134, 135, 136, 137 and/or 138 reaches another specific pressure value, the controller 20 may close the pneumatic valve 123 so as to block the purge gas from flowing into the stick(s) 131, 132, 133, 134, 135, 136, 137 and/or 138. In other words, the pneumatic valve 123 may cooperate with the pressure transmitter 125.

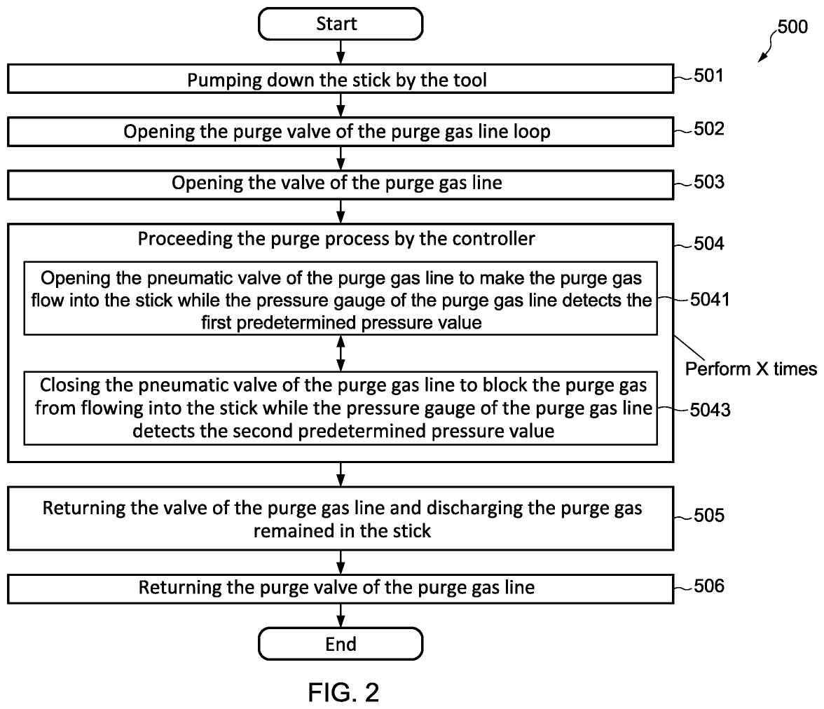

FIG. 2 is a flow chart representing exemplary operations of the method for manufacturing a semiconductor device by the semiconductor device manufacturing system, in accordance with some embodiments of the present disclosure. The method 500 as shown in FIG. 2 is related to purging the stick(s) 131, 132, 133, 134, 135, 136, 137 and/or 138 of the valve box module 10 before the semiconductor manufacturing tool(s) 31, 32, 33, 34, 35, 36, 37 and/or 38 is/are detached from the stick(s) 131, 132, 133, 134, 135, 136, 137 and/or 138 of the valve box module 10.

In operation 501, the stick(s) 131, 132, 133, 134, 135, 136, 137 and/or 138, which is coupled to the semiconductor manufacturing tool(s) 31, 32, 33, 34, 35, 36, 37 and/or 38 to be detached, is/are pumped down until the gas pressure in the stick(s) 131, 132, 133, 134, 135, 136, 137 and/or 138 is equal to or less than 0 psi.

In operation 502, the purge valve(s) 1201, 1202, 1203, 1204, 1205, 1206, 1207 and/or 1208 of the purge gas line loop, which is in fluid communication with the stick(s) 131, 132, 133, 134, 135, 136, 137 and/or 138 coupled to the semiconductor manufacturing tool(s) 31, 32, 33, 34, 35, 36, 37 and/or 38 to be detached, is/are opened.

In operation 503, the valve 121 of the purge gas line 12 is opened such that the purge gas from the purge source 120 flows into the VMB 10 and the purge gas line (downstream of the valve 121).

In operation 504, a purge process is performed. The controller 20 is configured to drive the pneumatic valve 123 and the pressure transmitter 125 of the purge gas line 12. The pressure transmitter 125 is configured to detect the gas pressure in the stick(s) 131, 132, 133, 134, 135, 136, 137 and/or 138 coupled to the semiconductor manufacturing tool(s) 31, 32, 33, 34, 35, 36, 37 and/or 38 to be detached and transfer the pressure value which it detected to the controller 20. Further, the controller 20 is configured to open the pneumatic valve 123 so that the purge gas flows into the stick(s) 131, 132, 133, 134, 135, 136, 137 and/or 138 coupled to the semiconductor manufacturing tool(s) 31, 32, 33, 34, 35, 36, 37 and/or 38 to be detached or close the pneumatic valve 123 so that the purge gas cannot flow into any stick based on the pressure value detected by the pressure transmitter 125.

In some embodiments of the present disclosure, in initial stage, the pneumatic valve 123 is closed and the pressure transmitter 125 is driven to detect the gas pressure in the stick(s) 131, 132, 133, 134, 135, 136, 137 and/or 138 coupled to the semiconductor manufacturing tool(s) 31, 32, 33, 34, 35, 36, 37 and/or 38 to be detached. At operation 5041, since the stick(s) 131, 132, 133, 134, 135, 136, 137 and/or 138 coupled to the semiconductor manufacturing tool(s) 31, 32, 33, 34, 35, 36, 37 and/or 38 to be detached is/are pumped down continuously and the pneumatic valve 123 is closed, the pressure transmitter 125 may detect that the gas pressure in the stick(s) 131, 132, 133, 134, 135, 136, 137 and/or 138 is equal to or less than 0 psi. When the pressure transmitter 125 detects that the gas pressure in the stick(s) 131, 132, 133, 134, 135, 136, 137 and/or 138 coupled to the semiconductor manufacturing tool(s) 31, 32, 33, 34, 35, 36, 37 and/or 38 to be detached reaches a first predetermined pressure value, the controller 20 is configured to open the pneumatic valve 123 such that the purge gas from the purge gas source 120 flows into the stick(s) 131, 132, 133, 134, 135, 136, 137 and/or 138 coupled to the semiconductor manufacturing tool(s) 31, 32, 33, 34, 35, 36, 37 and/or 38 to be detached. In some embodiments of the present disclosure, the first predetermined pressure value is equal to or less than 0 psi. At operation 5043, the gas pressure in the stick(s) 131, 132, 133, 134, 135, 136, 137 and/or 138 coupled to the semiconductor manufacturing tool(s) 31, 32, 33, 34, 35, 36, 37 and/or 38 to be detached is increased after the pneumatic valve 123 is opened and the purge gas flows into the stick(s). When the pressure transmitter 125 detects that the gas pressure in the stick(s) 131, 132, 133, 134, 135, 136, 137 and/or 138 coupled to the semiconductor manufacturing tool(s) 31, 32, 33, 34, 35, 36, 37 and/or 38 to be detached reaches a second predetermined pressure value, the controller 20 is configured to close the pneumatic valve 123 such that the purge gas is blocked from flowing into the stick(s) 131, 132, 133, 134, 135, 136, 137 and/or 138 coupled to the semiconductor manufacturing tool(s) 31, 32, 33, 34, 35, 36, 37 and/or 38 to be detached. In some embodiments of the present disclosure, the second predetermined pressure value is greater than 0 psi. Moreover, after the pneumatic valve is closed, the gas pressure in the stick(s) 131, 132, 133, 134, 135, 136, 137 and/or 138 coupled to the semiconductor manufacturing tool(s) 31, 32, 33, 34, 35, 36, 37 and/or 38 to be detached is decreased since the stick(s) is/are pumped down continuously. When the pressure transmitter 125 detects that the gas pressure in the stick(s) 131, 132, 133, 134, 135, 136, 137 and/or 138 coupled to the semiconductor manufacturing tool(s) 31, 32, 33, 34, 35, 36, 37 and/or 38 to be detached reaches the first predetermined pressure value, the controller 20 reopens the pneumatic valve 123 such that the purge gas flows into the stick(s) again.

The operations 5041 and 5043 may be performed a predetermined number (e.g., X number) of times or cycles. In some embodiments of the present disclosure, the predetermined number of cycles is 5-20 cycles. In some embodiments of the present disclosure, the predetermined number of cycles is 8-10 cycles. In some embodiments of the present disclosure, the predetermined number of cycles is 10 cycles. In some embodiments of the present disclosure, the predetermined number of cycles is larger than 20 cycles.

In the operation 505, after the operations 5041 and 5043 are performed the predetermined number of times or cycles, the valve 121 of the purge gas line 12 is returned to be closed and the stick(s) 131, 132, 133, 134, 135, 136, 137 and/or 138, which is/are coupled to the semiconductor manufacturing tool(s) 31, 32, 33, 34, 35, 36, 37 and/or 38 to be detached, continue(s) to be pumped down such that the purge gas remained in the stick(s) is discharged out of the stick(s) until the purge gas is exhausted of the stick(s).

In operation 506, the purge valve(s) 1201, 1202, 1203, 1204, 1205, 1206, 1207 and/or 1208 of the purge gas line loop, which is in fluid communication with the stick(s) 131, 132, 133, 134, 135, 136, 137 and/or 138 coupled to the semiconductor manufacturing tool(s) 31, 32, 33, 34, 35, 36, 37 and/or 38 to be detached, is closed.

The following uses a process of detaching the semiconductor manufacturing tools 31 and 33 as a reference to further illustrate the method 500. Once the semiconductor manufacturing tools 31 and 33 would be detached from the valve box module 10, as illustrated in operation 501, the sticks 131 and 133 of the valve box module 10, which are respectively coupled to the semiconductor manufacturing tools 31 and 33, are pumped down until the gas pressure in the sticks 131 and 133 is equal to or less than 0 psi.

As illustrated in operation 502, the purge valves 1201 and 1203, which are in communication with the sticks 131 and 133 respectively, are opened.

As illustrated in operation 503, the valve 121 of the purge gas line 12 is opened such that the purge gas from the purge source 120 flows into the purge gas line 12.

As illustrated in operation 504, the pneumatic valve 123 and the pressure transmitter of the purge gas line 12 are driven by the controller 20. As illustrated in operation 5041, the controller 20 is configured to open the pneumatic valve 123 such that the purge gas flows into the sticks 131 and 132 when the pressure transmitter detects that the gas pressure in the sticks 131 and 133 reaches the first predetermined pressure value (i.e., 0 psi). After the pneumatic valve 121 is opened and the purge gas flows into the sticks 131 and 133, the gas pressure in the sticks 131 and 133 are increased. As illustrated in operation 5043, when the pressure transmitter 125 detects that the gas pressure in the sticks 131 and 133 reaches the second predetermined pressure value (i.e., 20 psi), the controller 20 is configured to close the pneumatic valve 123 so that the purge gas cannot flow into the sticks 131 and 133. After the pneumatic valve 123 is closed by the controller 20, the gas pressure in the sticks 131 and 133 is decreased since the sticks 131 and 133 continue to be pumped down. When the pressure transmitter 125 detects that the gas pressure in the sticks 131 and 133 reaches the first predetermined pressure value again, the controller 20 is configured to reopen the pneumatic valve 123 so that the purge gas flows into the sticks 131 and 133 again. Such operations 5041 and 5043 are performed a predetermined number (i.e., 20) of cycles.

As illustrated in the operation 505, after the operations 5041 and 5043 are performed the predetermined number of cycles, the valve 121 of the purge gas line 12 is closed and the sticks 131 and 133 continue to be pumped down such that the purge gas remained in the sticks 131 and 133 is discharged out of the sticks 131 and 133.

As illustrated in the operation 506, the purge gas valves 1201 and 1203 are closed. Then the semiconductor manufacturing tools 31 and 33 could be detached from the valve box module 10.

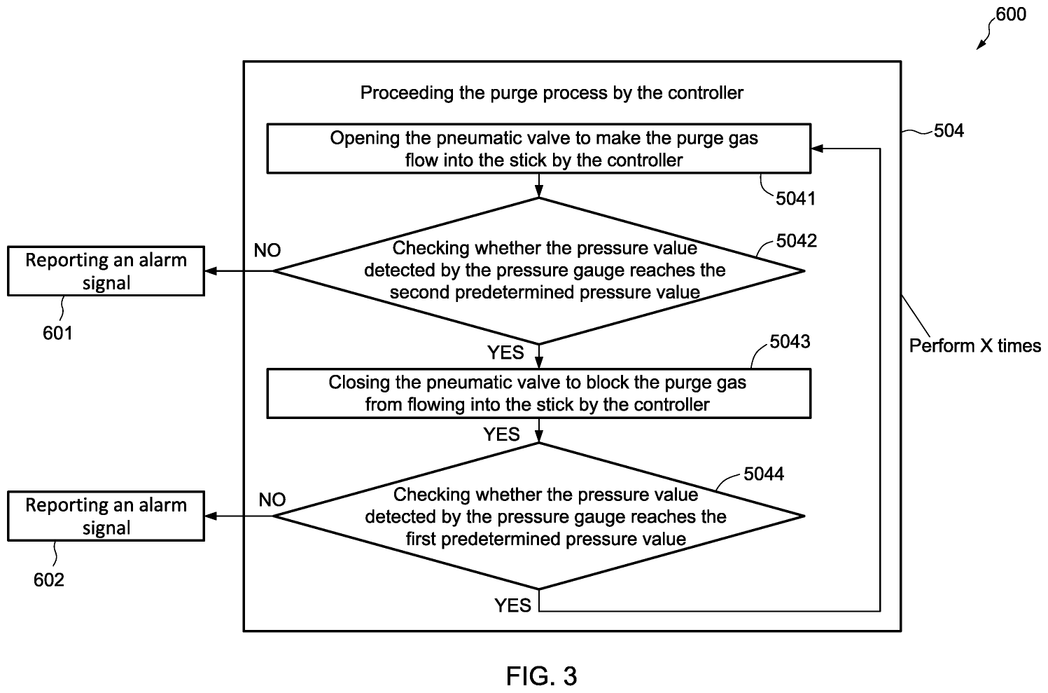

FIG. 3 is a flow chart representing exemplary operations of the method for manufacturing a semiconductor device by the semiconductor device manufacturing system, in accordance with some embodiments of the present disclosure. The method 600 as shown in FIG. 3 is related to reporting an alarm signal while the pressure transmitter detects that the purge gas pressure cannot reach the first or second predetermined pressure value.

As illustrated in the operation 5041, when the pressure transmitter 125 detects that the gas pressure in the stick(s) 131, 132, 133, 134, 135, 136, 137 and/or 138 coupled to the semiconductor manufacturing tool(s) 31, 32, 33, 34, 35, 36, 37 and/or 38 to be detached reaches a first predetermined pressure value, the controller 20 is configured to open the pneumatic valve 123 such that the purge gas from the purge gas source 120 flows into the stick(s) 131, 132, 133, 134, 135, 136, 137 and/or 138 coupled to the semiconductor manufacturing tool(s) 31, 32, 33, 34, 35, 36, 37 and/or 38 to be detached. The gas pressure in the stick(s) 131, 132, 133, 134, 135, 136, 137 and/or 138 coupled to the semiconductor manufacturing tool(s) 31, 32, 33, 34, 35, 36, 37 and/or 38 to be detached is increased after the pneumatic valve 123 is opened and the purge gas flows into the stick(s). Then the controller 20 closes the pneumatic valve 123 so as to block from flowing into the stick(s) when the gas pressure in the stick(s) reaches the second predetermined pressure value. In the operation 5042, the pressure transmitter 125 is configured to detect whether the gas pressure in the stick(s) reaches the second predetermined pressure value when the pneumatic valve 123 is opened. Once the pressure transmitter 125 detects that the gas pressure in the stick(s) is unable to reach the second predetermined pressure value, the controller 601 is configured to report an alarm signal to remind the user (the operation 601). Conversely, when the pressure transmitter 125 detects that the gas pressure in the stick(s) reaches the second predetermined pressure value, the controller 20 is configured to close the pneumatic valve 123 so as to block the purge gas from flowing into the stick(s) as illustrated in the operation 5043.

Moreover, after the pneumatic valve 123 is closed, the gas pressure in the stick(s) 131, 132, 133, 134, 135, 136, 137 and/or 138 coupled to the semiconductor manufacturing tool(s) 31, 32, 33, 34, 35, 36, 37 and/or 38 to be detached is decreased. Then the controller 20 opens the pneumatic valve 123 so as to make the purge gas flow into the stick(s) when the gas pressure in the stick(s) reaches the first predetermined pressure value. In the operation 5043, the pressure transmitter 125 is configured to detect whether the gas pressure in the stick(s) reaches the first predetermined pressure value when the pneumatic valve 123 is closed. Once the pressure transmitter 125 detects that the gas pressure in the stick(s) is unable to reach the first predetermined pressure value, the controller 601 is configured to report an alarm signal to remind the user (the operation 602). Conversely, when the pressure transmitter 125 detects that the gas pressure in the stick(s) reaches the first predetermined pressure value, the controller 20 is configured to open the pneumatic valve 123 such that the purge gas flows into the stick(s) as illustrated in the operation 5041.

The operations 5041, 5042, 5043 and 5044 may be performed a predetermined number (e.g., X number) of times or cycles. In some embodiments of the present disclosure, the predetermined number of cycles is 5-20 cycles. In some embodiments of the present disclosure, the predetermined number of cycles is 8-10 cycles. In some embodiments of the present disclosure, the predetermined number of cycles is 10 cycles. In some embodiments of the present disclosure, the predetermined number of cycles is larger than 20 cycles.

The following uses a process of detaching the semiconductor manufacturing tools 31 and 33 as a reference to further illustrate the method 600. Once the semiconductor manufacturing tools 31 and 33 would be detached from the valve box module 10, the purge process is performed on the sticks 131 and 133, which are respectively coupled to the semiconductor manufacturing tools 31 and 33. As illustrated in the operation 5041, when the pressure transmitter 125 detects that the gas pressure in the sticks 131 and 133 reaches the first predetermined pressure value (i.e., 0 psi), the controller 20 is configured to open the pneumatic valve 123 so as to make the purge gas from the purge gas source 120 flow into the sticks 131 and 133, and thus the gas pressure in the sticks 131 and 133 is increased. The pneumatic valve 123 is opened until the gas pressure in the sticks 131 and 133 reaches the second predetermined pressure value (i.e., 20 psi). As illustrated in the operation 5042, once the pressure transmitter 125 detects that the gas pressure in the sticks 131 and 133 is unable to reach 20 psi, the controller 20 is configured to report an alarm signal (the operation 601). Moreover, when the pressure transmitter 125 detects that the gas pressure in the sticks 131 and 133 reaches 20 psi, the controller 20 is configured to close the pneumatic valve 123 so as to block the purge gas from flowing into the sticks 131 and 133 as illustrated in the operation 5043. Further, the gas pressure in the sticks 131 and 133 are decreased since the purge gas does not flow into the sticks 131 and 133. The pneumatic valve 123 is closed until the gas pressure in the sticks 131 and 133 reaches 0 psi. As illustrated in the operation 5044, once the pressure transmitter 125 detects that the gas pressure in the sticks 131 and 133 is unable to reach 0 psi, the controller 20 is configured to report an alarm signal (the operation 602). Moreover, when the pressure transmitter 125 detects that the gas pressure in the sticks 131 and 133 reaches 0 psi, the controller 20 is configured to open the pneumatic valve 123 so as to make the purge gas flow into the sticks 131 and 133 as illustrated in the operation 5041. Such operations 5041, 5042, 5043 and 5044 are performed a predetermined number (i.e., 20) of cycles.

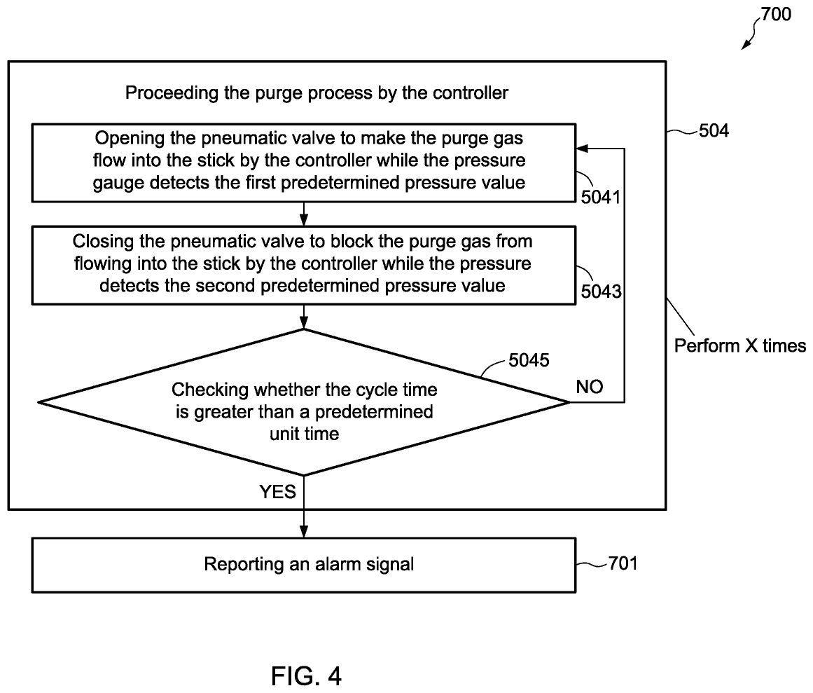

FIG. 4 is a flow chart representing exemplary operations of the method for manufacturing a semiconductor device by the semiconductor device manufacturing system, in accordance with some embodiments of the present disclosure. The method 700 as shown in FIG. 4 is related to reporting an alarm signal while the controller finds that the cycle time of the operations 5041 and 5043 is greater than a predetermined unit time.

As illustrated in the operation 5041, when the pressure transmitter 125 detects that the gas pressure in the stick(s) 131, 132, 133, 134, 135, 136, 137 and/or 138 coupled to the semiconductor manufacturing tool(s) 31, 32, 33, 34, 35, 36, 37 and/or 38 to be detached reaches a first predetermined pressure value, the controller 20 is configured to open the pneumatic valve 123 such that the purge gas from the purge gas source 120 flows into the stick(s) 131, 132, 133, 134, 135, 136, 137 and/or 138 coupled to the semiconductor manufacturing tool(s) 31, 32, 33, 34, 35, 36, 37 and/or 38 to be detached. The gas pressure in the stick(s) 131, 132, 133, 134, 135, 136, 137 and/or 138 coupled to the semiconductor manufacturing tool(s) 31, 32, 33, 34, 35, 36, 37 and/or 38 to be detached is increased after the pneumatic valve 123 is opened. Further, as illustrated in the operation 5043, when the pressure transmitter 125 detects that the gas pressure in the stick(s) reaches the second predetermined pressure value, the controller 20 is configured to close the pneumatic valve 123 so as to block the purge gas from flowing into the stick(s) as illustrated in the operation 5043. After the pneumatic valve 123 is closed, the gas pressure in the stick(s) is decreased. When the pressure transmitter 125 detects that the gas pressure in the stick(s) reaches the first predetermined pressure value, the controller 20 is configured to open the pneumatic valve 121 so as to make the purge gas flow into the stick(s) as illustrated in the operation 5041. The operations 5041 and 5043 may be performed a predetermined number (e.g., X number) of times or cycles. In the operation 5045, the controller 20 is configured to monitor the cycle time of the operations 5041 and 5043 during the performance of the operations 5041 and 5043. Once the controller 20 finds that the cycle time of the operations 5041 and 5043 is greater than a predetermined unit time, the controller 20 is configured to report an alarm signal to remind the user (the operation 701).

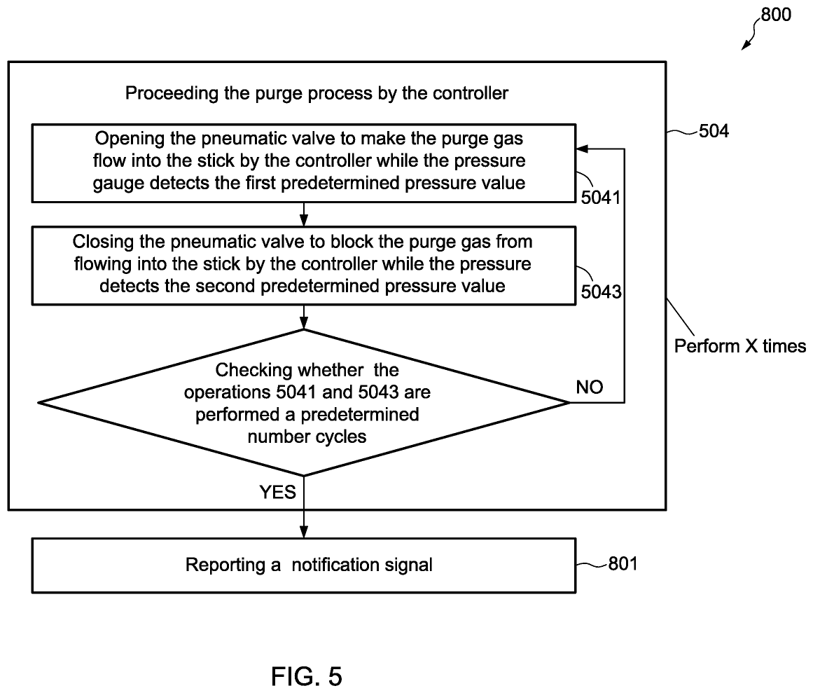

FIG. 5 is a flow chart representing exemplary operations of the method for manufacturing a semiconductor device by the semiconductor device manufacturing system, in accordance with some embodiments of the present disclosure. The method 800 as shown in FIG. 5 is related to reporting a notification signal while the controller finds that the operations 5041 and 5043 are performed a predetermined number of cycles.

As illustrated in the operation 504, the operations 5041 and 5043 may be performed a predetermined number cycle. In operation 801, once the controller 20 finds that the operations 5041 and 5043 have been performed the predetermined number of cycles, the controller 20 is configured to report a curing signal to remind the user.

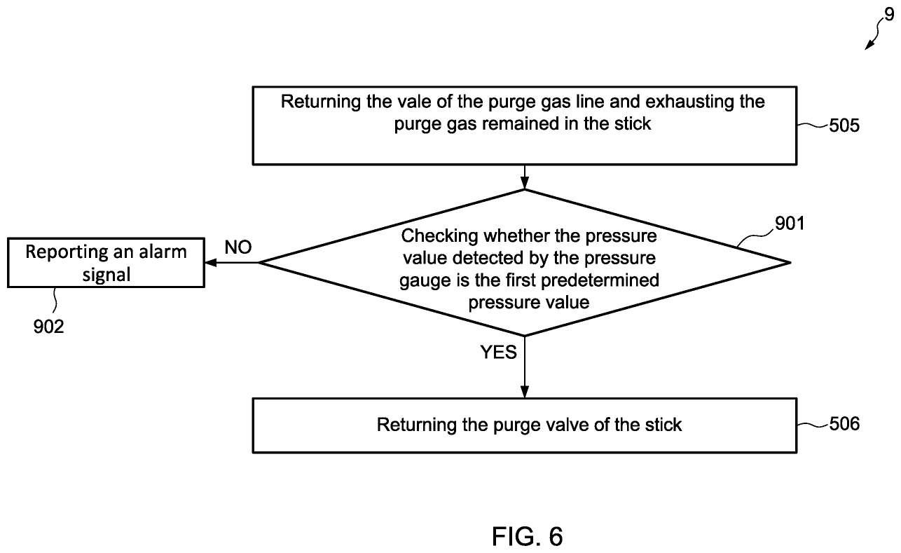

FIG. 6 is a flow chart representing exemplary operations of the method for manufacturing a semiconductor device by the semiconductor device manufacturing system, in accordance with some embodiments of the present disclosure. The method 9 as shown in FIG. 6 is related to reporting an alarm signal while the pressure transmitter detects that the gas pressure in the stick(s), which is coupled to the semiconductor manufacturing tool(s) to be detached, is greater than the first predetermined pressure value.

As illustrated in the operation 505, after the operations 5041 and 5043 are performed the predetermined number of times or cycles, the valve 121 of the purge gas line 12 is closed and the stick(s) 131, 132, 133, 134, 135, 136, 137 and/or 138, which is/are coupled to the semiconductor manufacturing tool(s) 31, 32, 33, 34, 35, 36, 37 and/or 38 to be detached, continue(s) to be pumped down such that the purge gas remained in the stick(s) is discharged out of the stick(s). In operation 801, once the pressure transmitter 125 detects that the gas pressure in the stick(s) is greater than the first predetermined pressure value after the purge gas valve(s) is/are closed, the controller 20 is configured to report an alarm signal to remind the user. Conversely, as illustrated in the operation 506, the purge valve(s) 1201, 1202, 1203, 1204, 1205, 1206, 1207 and/or 1208 of the purge gas line loop, which is in fluid communication with the stick(s) 131, 132, 133, 134, 135, 136, 137 and/or 138 coupled to the semiconductor manufacturing tool(s) 31, 32, 33, 34, 35, 36, 37 and/or 38 to be detached, is/are closed when the pressure transmitter 125 detects that the gas pressure in the stick(s) is the first predetermined pressure value.

Given the above, the pressure transmitter 125 is configured to monitor the gas pressure in the valve box module 10 during the purge process.

It will be further appreciated that the foregoing system may be used for performing a purge process on the valve box module more efficiently. The user may set the cycle purge times and the pressure setting by the controller and then the purge process could be performed automatically. The number of the semiconductor manufacturing tools which need to be purged and detached may be increased. In addition, the safety of detaching the semiconductor manufacturing tools may be improved since the purge process could be performed accurately and reliably.

According to some embodiments of the present disclosure, a valve box module for a semiconductor device manufacturing system includes at least one stick and a first gas inlet. The first gas inlet is in fluid communication with the at least one stick and configured to supply a purge gas into the at least one stick. The first gas line may include a pneumatic valve and a pressure transmitter downstream of the pneumatic valve. Further, the pneumatic valve is configured to cooperate with the pressure transmitter.

According to some other embodiments of the present disclosure, a semiconductor device manufacturing system comprises: a valve box module, a controller, a purge gas source and at least one semiconductor manufacturing tool. The valve box module includes at least one stick and a first gas line in fluid communication with the at least one stick. Further, the first gas line includes a pneumatic valve and a pressure transmitter downstream of the pneumatic valve. The controller connects to the pneumatic valve and the pressure transmitter of the first gas line. The purge gas source is in fluid communication with the first gas line. The at least one semiconductor manufacturing tool is coupled to the at least one stick.

According to still some other embodiments of the present disclosure, a method of manufacturing a semiconductor device, comprising: pumping down a stick, wherein the stick is in fluid communication with a semiconductor manufacturing tool; opening a purge valve of a first gas line, wherein the first gas line is in fluid communication with the stick; opening a valve of the first gas line to make a purge gas flow into the first gas line, wherein the valve is upstream of the purge valve; controlling a pneumatic valve and a pressure transmitter of the first gas line to proceed a purge process by a controller, wherein the pneumatic valve and the pressure transmitter are located between the valve and the purge valve, and wherein the pressure transmitter is downstream of the pneumatic valve, opening the pneumatic valve to make the purge gas flow into the stick by the controller while the pressure transmitter detects a first predetermined pressure value and closing the pneumatic valve to block the purge gas from flowing into the stick by the controller while the pressure detects a second predetermined pressure value, wherein the second predetermined pressure value is higher than the first predetermined pressure value; and alternating opening the pneumatic valve to make the purge gas flow into the stick and closing the pneumatic valve to block the purge gas from flowing into the gas outlet stick for a predetermined number of cycles.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A valve box module for a semiconductor device manufacturing system, comprising:
at least one stick; and
a first gas line in fluid communication with the at least one stick and configured to supply a purge gas into the at least one stick;
wherein the first gas line comprises a pneumatic valve and a pressure transmitter downstream of the pneumatic valve, and wherein the pneumatic valve is configured to cooperate with the pressure transmitter.

2. The valve box module of claim 1, further comprising a second gas line in fluid communication with the at least one stick and configured to supply a process gas into the at least one stick.

3. The valve box module of claim 1, wherein the first gas line comprises a valve therein, upstream of the pneumatic valve, and wherein the valve is configured to be selectively opened or closed to control the purge gas to pass through the first gas line.

4. The valve box module of claim 3, wherein the first gas line comprises a regulator valve between the valve and the pneumatic valve.

5. The valve box module of claim 1, wherein the first gas line comprises a purge valve adjacent to a joint between the stick and the first gas line.

6. The valve box module of claim 1, wherein the first gas line comprises a check valve between the pneumatic valve and the pressure transmitter.

7. A semiconductor device manufacturing system, comprising:
a valve box module, comprising:
at least one stick; and
a first gas line in fluid communication with the at least one stick, wherein the first gas line comprises a pneumatic valve and a pressure transmitter downstream of the pneumatic valve:
a controller connecting the pneumatic valve and the pressure transmitter of the first gas line;
a purge gas source in fluid communication with the first gas line; and
at least one semiconductor manufacturing tool coupled to the at least one stick.

8. The semiconductor device manufacturing system of claim 7, wherein the valve box module comprises a second gas line in fluid communication with the at least one stick, and wherein the semiconductor device manufacturing system comprises a process gas source in fluid communication with the second gas line.

9. The semiconductor device manufacturing system of claim 7, wherein the controller is configured to receive a pressure value from the pressure transmitter and drive the pneumatic valve based on the pressure value from the pressure transmitter.

10. The semiconductor device manufacturing system of claim 7, wherein the controller is configured to receive a pressure value from the pressure transmitter and report an alarm signal based on the pressure value from the pressure transmitter.

11. The semiconductor device manufacturing system of claim 7, wherein the controller includes a programmable logic controller.

12. A method of manufacturing a semiconductor device, comprising:
pumping down a stick, wherein the stick is in fluid communication with a semiconductor manufacturing tool;
opening a purge valve of a first gas line, wherein the first gas line is in fluid communication with the stick;
opening a valve of the first gas line to make a purge gas flow into the first gas line, wherein the valve is upstream of the purge valve;
controlling a pneumatic valve and a pressure transmitter of the first gas line to proceed a purge process by a controller, wherein the pneumatic valve and the pressure transmitter are located between the valve and the purge valve, and wherein the pressure transmitter is downstream of the pneumatic valve;
opening the pneumatic valve to make the purge gas flow into the stick by the controller while the pressure transmitter detects a first pressure value and closing the pneumatic valve to block the purge gas from flowing into the stick by the controller while the pressure detects a second pressure value, wherein the second pressure value is higher than the first pressure value; and
alternating opening the pneumatic valve to make the purge gas flow into the stick and closing the pneumatic valve to block the purge gas from flowing into the stick for a number of cycles.

13. The method of claim 12, wherein the first pressure value is less than or equal to 0 psi and wherein the second pressure value is greater than 0 psi.

14. The method of claim 12, further comprising: returning the valve of the first gas line and exhausting the purge gas remained in the stick after alternating opening the pneumatic valve to make the purge gas flow into the stick and closing the pneumatic valve to block the purge gas from flowing into the gas outlet stick for the number of cycles.

15. The method of claim 14, further comprising: returning the purge valve of the first gas line after returning the valve of the first gas line and exhausting the purge gas remained in the stick.

16. The method of claim 12, wherein the controller is configured to report an alarm signal after the pneumatic valve is opened and a pressure value detected by the pressure transmitter is lower than the second pressure value or after the pneumatic valve is closed and a pressure value detected by the pressure transmitter is higher than the first pressure value.

17. The method of claim 12, wherein the controller is configured to report an alarm signal while a cycle time of alternating opening the pneumatic valve to make the purge gas flow into the stick and closing the pneumatic valve to block the purge gas from flowing into the gas outlet stick is greater than a unit time.

18. The method of claim 14, wherein the controller is configured to report an alarm signal by the controller when the pressure transmitter detects a pressure value greater than 0 psi after returning the valve of the first gas line and exhausting the purge gas remained in the stick.

19. The method of claim 12, further comprising: monitoring a pressure of the purge gas during the purge process.

20. The method of claim 12, wherein the controller is configured to report a notification signal after alternating opening the pneumatic valve to make the purge gas flow into the stick and closing the pneumatic valve to block the purge gas from flowing into the gas outlet stick for the number of cycles.
